(19) United States
(12) Patent Application Publication
(10) Pub. No.: US 2012/0290236 A1
(43) Pub. Date: Nov. 15, 2012

(54) BATTERY CONDITION DETECTING APPARATUS

(75) Inventor: Yoshihide Majima, Tokyo (JP)

(73) Assignee: Mitsumi Electric Co., Ltd, Tokyo (JP)

(21) Appl. No.: 13/519,365

(22) PCT Filed: Jan. 20, 2011
(86) PCT No.: PCT/JP2011/050961

§ 371 Date: Jun. 27, 2012

(30) Foreign Application Priority Data
Feb. 19, 2010 (JP) 2010-035128

(51) Int. Cl. G01R 31/36; G06F 19/00

(52) U.S. Cl. 702/63

(57) ABSTRACT

There is provided a battery condition detecting apparatus including a voltage detecting unit configured to detect an open voltage of a secondary battery, and a charging rate calculating unit configured to calculate a charging rate by applying a charged open voltage obtained by charging the secondary battery and detected by the voltage detecting unit to a first battery property indicative of a relationship between the charged open voltage and the first battery property, and for calculating the charging rate by applying a discharged open voltage obtained by discharging the secondary battery and detected by the voltage detecting unit to a second battery property indicative of a relationship between the discharged open voltage and the second battery property.

### TECHNICAL FIELD

The present invention generally relates to a battery condition detecting apparatus for detecting a condition of a secondary battery.

### BACKGROUND ART

As a related art, for example, Patent Document 1 discloses a method of assuming an output voltage continuously being output for a predetermined period of a stable voltage as an open voltage of the secondary battery and estimating a residual quantity of the secondary battery based on a property between the open voltage and the residual quantity. Patent Document 1 discloses that a change of a battery voltage due to a change of a battery current shows a predetermined delay, and the battery voltage is stabilized after a predetermined period called a relaxation time.

As described, a secondary battery such as a lithium-ion battery shows a high correlation between a charging rate and an open voltage. Therefore, the charging rate of the secondary battery may be estimated using the correlation.
[Patent Document 1] Japanese Laid-open Patent Publication No. 2007-178215

### DISCLOSURE OF THE INVENTION

### Problems to be Solved by the Invention

However, it is known by the inventors of the present invention from actual measurements that if residual capacities of a secondary battery are the same or charging rates of the secondary battery are the same between a case where the secondary battery is charged and thereafter is left to be in a no load state and a case where the secondary battery is discharged and thereafter is left to be in the no load state, open voltages of the secondary batteries are not equalized between the cases after elapsing several days from a time point when the secondary battery had been charged or discharged. Therefore, if a charging rate is acquired from an open voltage after the charging based on the correlation between the open voltage and the charging rate, a substantial error may be included in the acquired charging rate.

The object of the present invention is to provide a battery condition detecting apparatus which can accurately calculate the charging rates of secondary batteries.

### Means for Solving Problems

In order to achieve the above object, the present invention may be to provide a battery condition detecting apparatus including a voltage detecting unit configured to detect an open voltage of a secondary battery, and a charging rate calculating unit configured to calculate a charging rate by applying a charged open voltage obtained by charging the secondary battery and detected by the voltage detecting unit to a first battery property indicative of a relationship between the charged open voltage and the first battery property, and for calculating the charging rate by applying a discharged open voltage obtained by discharging the secondary battery and detected by the voltage detecting unit to a second battery property indicative of a relationship between the discharged open voltage and the second battery property.

### Effect of the Invention

According to the present invention, the charging rate of a secondary battery can be accurately calculated.

### BRIEF DESCRIPTION OF DRAWINGS

FIG. 1 illustrates an entire structure of a battery monitoring system 20 including a battery condition detecting apparatus 1 of an embodiment of the present invention.

FIG. 2 illustrates actually measured data indicative of a correlation of “open voltage-charging rate”.

FIG. 3 illustrates time charts for applying tables on charging and discharging sides.

FIG. 4A illustrates an operation flow of an operating part 24.

FIG. 4B illustrates the operation flow of the operating part 24.

FIG. 5 illustrates a property of “open voltage-ambient temperature”.

### BEST MODE FOR CARRYING OUT THE INVENTION

A description is given below, with reference to the figures of the embodiments of the present invention.

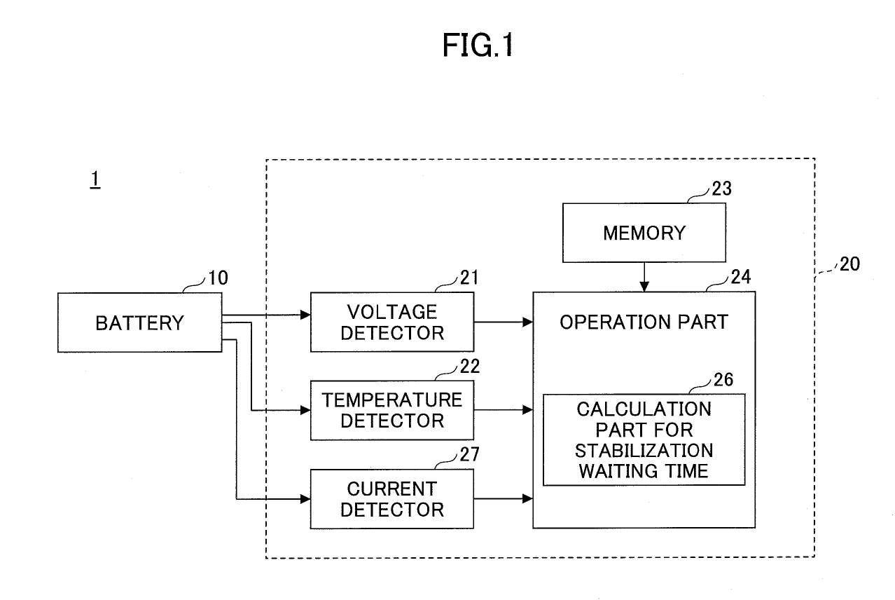

FIG. 1 illustrates an entire structure of a battery monitoring system 1 including a battery condition detecting apparatus 20 of an embodiment of the present invention. The battery monitoring system 1 includes a secondary battery 10 and the battery condition detecting apparatus 20 for detecting a condition of the secondary battery 10. An exemplary secondary battery 10 is a lithium-ion battery, a nickel-metal hydride battery, or the like. The battery condition detecting apparatus 20 includes a voltage detector 21, a temperature detector 22, a memory 23 and an operation part 24. The battery condition detecting apparatus 20 may include a current detector 27 for detecting a charging or discharging current (input and output current) for the secondary battery 10. The components such as the voltage detector 21 of the battery condition detecting apparatus 20 may be formed by, for example, an integrated circuit.

The voltage detector 21 is a unit configured to detect an output voltage from the secondary battery 10. The voltage detector 21 outputs detected data of the output voltage from the secondary battery 10 to the operation part 24. The voltage detector 21 detects the output voltage from the secondary battery 10 at least under a condition, in which the charging or discharging current (an input and output current) for the secondary battery 10 is a predetermined first threshold (for example, zero or a value slightly greater than zero) or smaller, as an open voltage of the secondary battery 10. The voltage detector 21 may detect an interpolar voltage measured between poles of a stabilized secondary battery 10 when the poles are electrically opened or connected with a high impedance. Further, the voltage detector 21 may detect the interpolar voltage measured between the poles of the secondary battery 10 connected to a load causing a standby current (e.g., 1 mA or smaller) to be supplied to an external device such as a mobile phone or a game machine, which is to be connected to the battery condition detecting apparatus 20, as the open voltage of the secondary battery 10.

The temperature detector 22 is a temperature detecting unit configured to detect an ambient temperature Ta of the secondary battery 10. The voltage detector 22 outputs detected data of the ambient temperature Ta to the operation part 24. The temperature detector 22 may detect the temperature of the secondary battery 10 as the ambient temperature Ta.

The operation part 24 is a unit configured to estimate a condition of residual quantity (especially, a charging rate) of the secondary battery 10 based on detected data of the voltage detected by the voltage detector 21, detected data of the temperature detected by the temperature detector 22, and a battery property inherent in the secondary battery 10 previously stored in the memory 23. An exemplary operation part 24 is a microcomputer in which a central processing unit or the like is integrated. An exemplary memory 23 for storing a property parameter for specifying the battery property of the secondary battery 10 is an EEPROM or a flash memory.

The operation part 24 includes a calculation part 26 for a stabilization waiting time T for voltage stabilization as a unit configured to calculate the voltage stabilization waiting time T used for stabilizing the output voltage from the secondary battery 10. The voltage stabilization waiting time T starts when the discharging current (or the charging current) for the secondary battery 10 becomes a predetermined first threshold value (e.g., zero or a value slightly greater than zero) or smaller and ends when the voltage variation of the secondary battery 10 per a unit time becomes a second predetermined value (e.g., zero or a value slightly greater than zero) or smaller. Said differently, the state of the stable voltage in which the output voltage from the secondary battery 10 is stabilized corresponds to a state in which the discharging current (or the charging current) of the secondary battery 10 continues for the stabilization waiting time T or longer. The calculation part for the stabilization waiting time 26 preferably calculates the stabilization waiting time T for transitioning to the state of the stable voltage by a timer (a time measuring unit) of the operation part 24 based on, for example, at least any one of detection values such as the output voltage from the secondary battery 10, the charging or discharging current and the ambient temperature and a calculation value of a capacity holding rate (a deterioration rate) obtained based on the detection values. The method of calculating the stabilization waiting time T is not specifically limited and may be a known method.

The operation part 24 is a charging rate calculating unit configured to apply the open voltage of the charged secondary battery 10 detected by the voltage detector 21 to first battery property indicative of a relationship between the open voltage after charging the secondary battery 10 and the charging rate of the secondary battery 10 and calculating the charging rate of the secondary battery 10, and for applying the open voltage of the discharged secondary battery 10 detected by the voltage detector 21 to second battery property indicative of a relationship between the open voltage after discharging the secondary battery 10 and the charging rate of the secondary battery 10 and calculating the charging rate of the secondary battery 10. First property data for specifying the first battery property and second property data for specifying the second battery property are previously stored in the memory 23.

When the fully charged capacity of the secondary battery 10 is represented by 100, a rate of the residual quantity of the secondary battery 10 is expressed in percent figures as the charging rate. The battery property indicative of the correlation of “open voltage−charging rate” used for calculating the charging rate may be indicated by a correction table or a correction function. Data inside the correction table and a coefficient of the correction function are stored in the memory 23 as the property data. The operation part 24 calculates or corrects the charging rate in response to the open voltage measured by the voltage detector 21. This calculation may be based on the correction table and the correction function, in which the property data read out from the memory 23 are reflected.

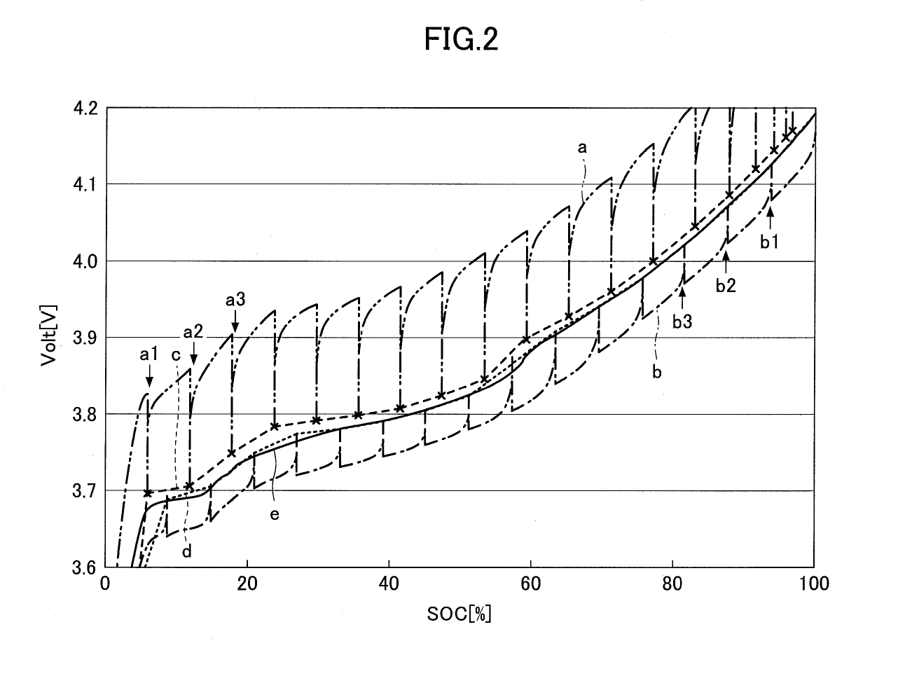

The property data determined based on the result (see FIG. 2) which is obtained by actually measuring the correlation of “open voltage-charging rate” are stored in the memory 23. Referring to FIG. 2, a property graph a corresponds to actually measured data obtained by repeating charging with electricity of a predetermined quantity (50 mAh) from a condition where the residual quantity is 0 mAh and changing to no-load for a predetermined period (4 hours). As illustrated in the property graph a, the interpolar voltage increases during charging. At the points a1, a2, a3, . . . under the no-load for 4 hours, the open voltage decreases. In this case, information of “open voltage−charging rate” under the no-load for 4 hours after charging is stored in the memory 23 as open voltage data for each charging rate after charging the secondary battery 10. The property graph c is obtained by connecting the open voltages under the no-load for 4 hours after charging.

Meanwhile, the property graph b is obtained by repeating discharging by a predetermined quantity (50 mAh) from the fully charged state and the no-load for 4 hours. As illustrated in the property graph b, the open voltage decreases during discharging. At the points b1, b2, b3, under the no-load for four hours, the open voltage increases. In this case, information of “open voltage−charging rate” under the no-load for 4 hours after discharging is stored in the memory 23 as open voltage data for each charging rate after discharging the secondary battery 10. The property graph d is obtained by connecting the open voltages under the no-load for 4 hours after discharging. The property graph d substantially overlaps a property graph e obtained by constantly discharging with an electric current of 3 mA from the fully charged state.

The above described conditions of the discharged capacity of 50 mAh and the no-load time of 4 hours can be optimized in response to a processing method of the system.

Open voltage data for each charging rate after charging which are stored in the memory 23 and the open voltage data for each charging rate after discharging may be voltage data obtained by measurement. However, any one of the open voltage data for each charging rate after charging and the open voltage data for each charging rate after discharging may be expressed by a difference between the open voltage data for each charging rate after charging and the open voltage data for each charging rate after discharging. Said differently, a value of any one of the open voltage data for each charging rate after charging and the open voltage data for each charging rate after discharging may not be stored in the memory 23. With this, it is possible to reduce a memory capacity for the memory 23. The operation part 24 can calculate the other open voltage data, based on one of the open voltage data for each charging rate after charging and the open voltage data for each charging rate after discharging and a difference between the open voltage data for each charging rate after charging and the open voltage data for each charging rate after discharging.

A difference voltage for each charging rate between the property graphs a and b corresponds to difference voltage data between the open voltage data for each charging rate after charging and the open voltage data for each charging rate after discharging. For example, the open voltage after charging the secondary battery may be stored as the measured voltage data, and the open voltage data after discharging the secondary battery are stored as the difference voltage data. On the contrary, the open voltage after discharging the secondary battery is stored as the measured voltage data, and the open voltage data after charging the secondary battery are stored as the difference voltage data. As illustrated in FIG. 2, the absolute value of the open voltage is in the order of several V. However, the difference voltage is in the order of several tens mV. Therefore, in comparison with the case where the absolute values of the open voltages after charging and discharging are stored, the necessary memory capacity of the memory 23 can be drastically reduced by storing the difference data instead of one of the open voltages after charging and discharging.

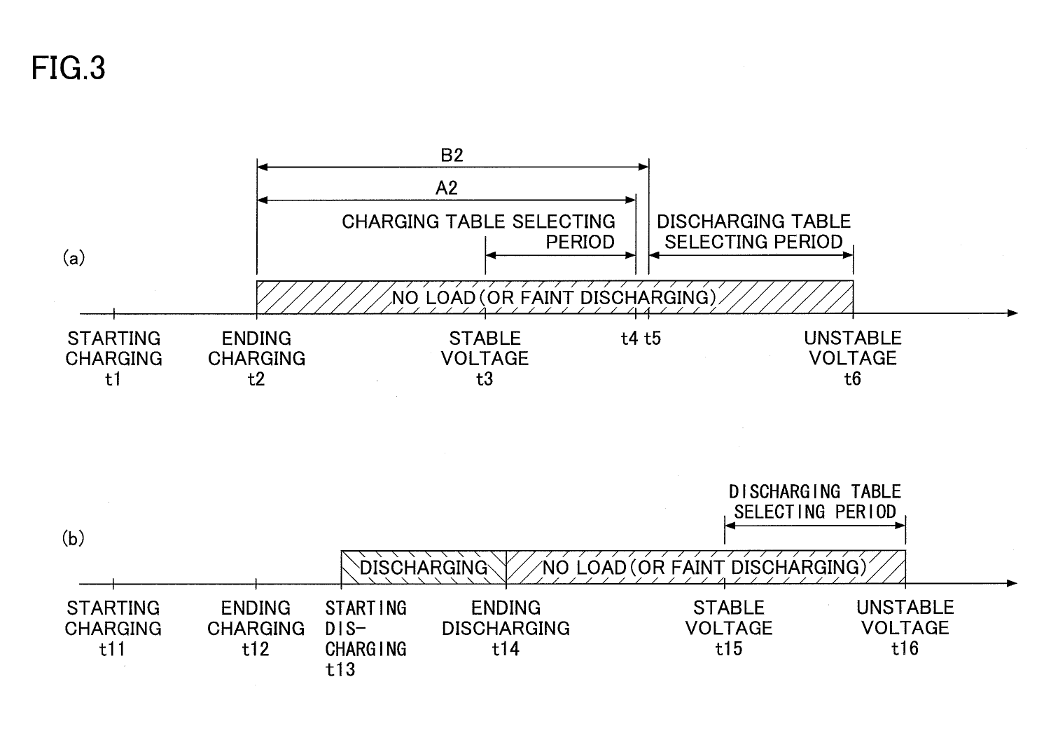

Next, a processing method of calculating the charging rate with the operating part 24 is described. The operation part 24 selects one of a “charging table” in which an open voltage data group for each charging rate after charging is stored and a “discharging table” in which an open voltage data group for each charging rate after discharging is stored. This selection may be in response to, for example, the discharged capacity after ending charging the secondary battery 10 and an elapsed time after ending charging the secondary battery 10. The charging rate is calculated based on the selected table. FIG. 3 illustrates periods to which the charging table and the discharging table are applied. The charging period of the secondary battery 10 corresponds to a period between a time point t1 of starting charging and a time point t2 of ending charging.

As illustrated in (a) of FIG. 3, the operation part 24 calculates the charging rate based on the charging table using the “open voltage after charging” as the open voltage detected by the voltage detector 21 in a case where it is determined that the output voltage of the secondary battery 10 is stabilized (for example, the above described stabilization waiting time T such as a period between the time point t2 of ending charging and the time point t3 of a stable voltage elapses) while there is no-load or faint discharging after the time point t2 of ending discharging so as not to discharge the secondary battery 10 with a predetermined reference capacity A1 or greater.

However, a loading state after the time point t2 of ending charging does not always become no load. Depending on an external device (not illustrated, e.g., a mobile phone or a game machine) using the secondary battery 10 as a power source, the loading state after the time point t2 of ending charging does not always become no load. The external device may cause faint discharging, thereby causing a consumption current of about several mA to continuously flow. Therefore, it is assumed to be inappropriate to treat the open voltage detected at a time point after a certain period from the time point t2 of ending charging as the “open voltage after charging”. Therefore, in the period for which the charging rate is calculated based on the charging table, the elapsed time after the time point t2 of ending charging is required to be the predetermined reference time A2 or shorter. The reference capacity A1 and the reference time A2 may be determined in response to a property of cells of the secondary battery 10 and the consumption current of the external device supplied by the secondary battery 10.

The operation unit 24 may not easily determine whether the discharging table or the charging table is used in order to calculate an accurate charging rate until a predetermined discharging quantity or a predetermined discharging time occurs in a case where the secondary battery is discharged with the reference capacity A1 or greater after the time point t2 of ending charging. Therefore, the operation part 24 stops a process of calculating the charging rate using the output voltage of the secondary battery 10 until a predetermined discharged quantity (e.g., a reference capacity B1 greater than a reference capacity A1) or a predetermined discharged time (e.g., a reference time B2 longer than the reference time A2) occurs after the time point t2 of ending discharging thereby preventing a calculation error from increasing.

As illustrated in (a) of FIG. 3, the operation part 24 calculates the charging rate based on the discharging table using the open voltage detected by the voltage detector 21 as the “open voltage after discharging” in a case where the output voltage is stabilized after the time point t3 of starting stabilizing the output voltage of the secondary battery 10 after a predetermined discharged capacity (e.g., the reference capacity B1) is discharged by faint discharging after the time point t2 of ending charging (e.g., after a predetermined reference time B2 or longer elapses from the time point t2 of ending charging). As illustrated in (b) of FIG. 3, the operation part 24 calculates the charging rate based on the discharging table. This calculation uses the open voltage detected by the voltage detector 21 as the “open voltage after discharging” in a case where the output voltage is stabilized after a time point t15 of starting stabilizing the output voltage of the secondary battery 10 after a predetermined discharged capacity (e.g., the reference capacity B1) is discharged by great discharging at time points t13 to t14 greater than the faint discharging after a time point t12 of ending charging (or after the predetermined reference time B2 or longer elapses from the time point t2 of ending charging). Referring to (b) of FIG. 3, the period between the time point t14 of ending discharging and the time point t15 of starting stabilizing the voltage corresponds to the above-described stabilization waiting time T.

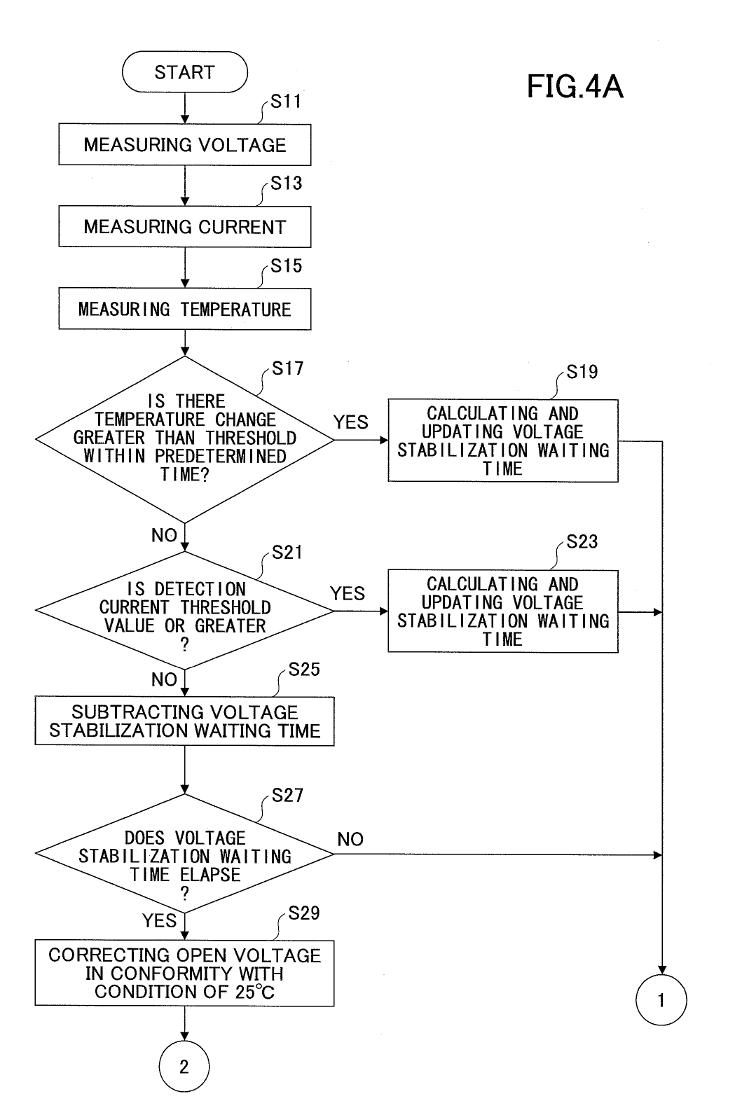

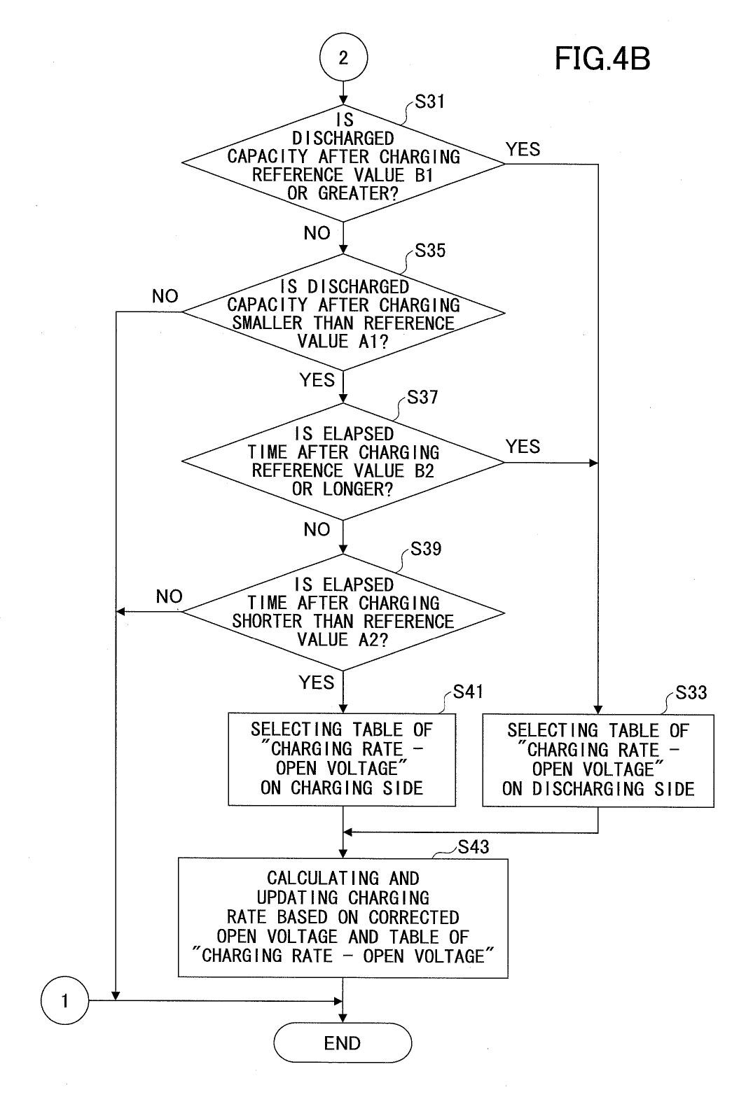

Referring to FIG. 4A and FIG. 4B, the charging rate of the secondary battery 10 is calculated. The operation part 24 starts operations in conformity with a flow illustrated in FIG. 4A and FIG. 4B when a charging or discharging current for the secondary battery 10 being a predetermined first threshold value or smaller is detected.

The operation part 24 measures the output voltage of the secondary battery 10 as the open voltage with the voltage detector 21 in step S11. The operation part 24 measures the charging or discharging current for the secondary battery 10 with the current detector 27 in step S13. The operation part 24 measures an ambient temperature of the secondary battery 10 with the temperature detector 22 in step S15. The order of step S11 to step S15 is not specifically limited.

In a case where at least one of an ambient temperature Ta of the secondary battery 10 and the charging or discharging current varies beyond predetermined reference values before the calculated stabilization waiting time T elapses, the calculation part for the stabilization waiting time 26 calculates the stabilization waiting time T again using a value changed in conformity with the variation and updates by changing a register value of the stabilization waiting time T so as to be the calculation value which is calculated again in steps S17 to S23.

For example, in a case where the temperature exceeding the reference value is detected during a predetermined period, the stabilization waiting time T necessary after detecting the temperature is set again. Even though the variation of the ambient temperature of the secondary battery 10 is stabilized, there is a time lag until the temperature of the secondary battery 10 is stabilized. Therefore, a battery condition such as a measured open voltage and a battery temperature may not be stabilized. Therefore, by estimating a condition of the residual quantity of the secondary battery 10 based on the battery condition such as the ambient temperature Ta and the ambient temperature Ta before the variation of the charging or discharging current, an estimated error may increase. However, by prolonging the stabilization waiting time T as in steps S17 to S23, it is possible to prevent the estimated error from increasing. As described, by prolonging the stabilization waiting time T in the case where the temperature change or the like is detected, it is possible to measure the battery condition such as the further accurate open voltage and the ambient temperature Ta. Thus, it is possible to delay a timing of calculating the charging rate described later and to improve the accuracy of the calculated charging rate.

For example, in step S17, in a case where a variation of the ambient temperature Ta exceeding the reference value is detected during the predetermined time after detecting the charging or discharging current for the secondary battery 10 having the predetermined threshold value or smaller, the calculation part for the stabilization waiting time 26 calculates the stabilization waiting time T corresponding to the capacity holding rate K, which has already been calculated, and an ambient temperature T, obtained after the variation, and updates by changing the register value to the calculation value calculated again in step S19.

Further, for example, in step S21, the calculation part for the stabilization waiting time 26 calculates the stabilization waiting times T corresponding to the ambient temperature Ta, which has already been measured, and to the capacity holding rate K after the variation again, and updates by changing the register value to the calculation value calculated again in step S23. This is because a flow of the charging or discharging current having the predetermined threshold value or greater is a condition for calculating the stabilization waiting time T again and may cause the variation of the capacity holding rate K

The operation part 24 subtracts a predetermined value from the register value of the stabilization waiting time T in a case where both of the ambient temperature Ta of the secondary battery 10 and the charging or discharging current do not exceed the predetermined reference values in steps S17 and S21 (e.g., variations within predetermined ranges) in step S25. Then, the operation part 24 determines whether the stabilization waiting time T elapses, or said differently, whether the register value of the stabilization waiting time T becomes zero in step S27. If the stabilization waiting time T does not elapse, the process returns to START of this flowchart illustrated in FIG. 4A.

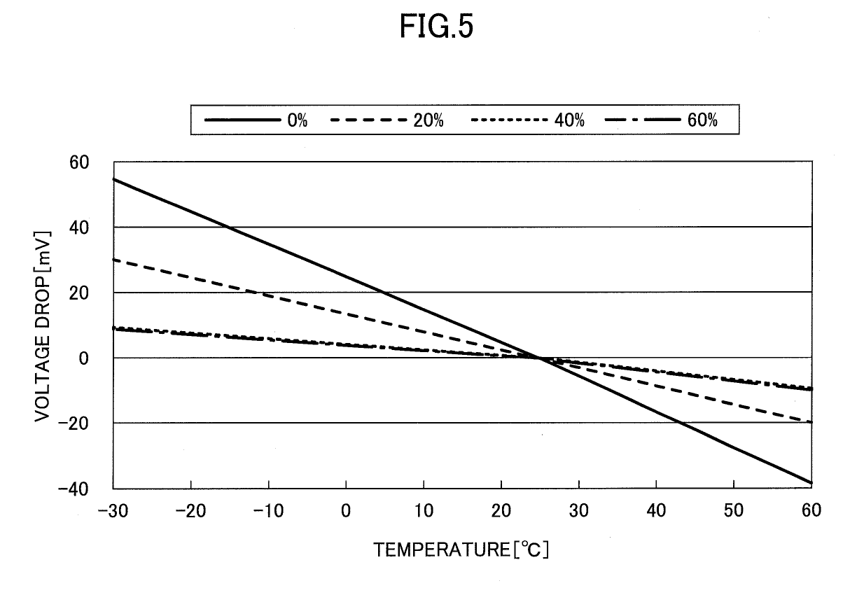

If the stabilization waiting time T elapses, the operation part 24 corrects the open voltage measured under the stable voltage after the stabilization waiting time T (or the open voltage measured in step S11) so as to conform to a condition of 25° C. based on the property data indicative of the property of “open voltage-ambient temperature” (FIG. 5), previously stored in the memory 23, and in response to the ambient temperature Ta measured under the stable voltage after the stabilization waiting time T (or the ambient temperature Ta measured in step S15) in step S29. The property of “open voltage-ambient temperature” (FIG. 5) illustrates an offset value of the open voltage at various temperatures including 25° C. FIG. 5 illustrates the offset amounts of the open voltage for each charging rate of the secondary battery 10. With this, it is possible to correct the open voltage using the temperature and to suppress an increment of the calculation error of the charging rate.

Referring to FIG. 4B, the operation part 24 determines whether the discharged capacity from the time point of ending charging is the predetermined reference capacity B1 or greater in step S31. If the operation part 24 determines that the discharged capacity is equal to the reference capacity B1 or greater, great discharge may have occurred after the time point t2 of ending charging as illustrated in (b) of FIG. 3. After the great discharging, a loading state of no load or faint discharging may continue. Then, because it is determined that the output voltage is stabilized at the timing t15, the operation part 24 selects the “discharging table” in which a relationship between the charging rate after discharging and the open voltage is specified as a table for calculating the charging rate in step S33.

The operation part 24 calculates the charging rate corresponding to the open voltage which is corrected in conformity with the condition of 25° C. in step S29 as a residual quantity state of the secondary battery 10 based on the property data indicative of the “discharging table” stored in the memory 23 and updates by changing the register value of the charging rate to the calculation value in step S43.

Meanwhile, in a case where the operation part 24 determines that the discharging capacity is not the reference capacity B1 or greater in step S31, it is determined whether the discharged capacity from the time point of ending charging is smaller than the reference capacity A1 in step S35. The reference capacity A1 is smaller than the reference capacity B1. In a case where the operation part 24 determines that the discharged capacity is not smaller than the reference voltage, the discharged quantity from the time point t2 is great and it is difficult to determine whether the open voltage detected by the voltage detector 21 is whether the open voltage after charging or the open voltage after discharging. Therefore, the register value of the charging rate is not updated.

If the operation part 24 determines that the discharged capacity is smaller than the reference capacity A1 in step S35, it is determined whether the elapsed time from the time point of ending charging is the predetermined first reference time B2 or greater in step S37. The operation part 24 determines that the open voltage detected by the voltage detector 21 is the “open voltage after discharging” in the case where the elapsed time from the time point of ending charging is the first reference time B2 or greater, and selects the discharging table as a table for calculating the charging rate in step S33. The process in step S43 is similar to the above. For example, in the state illustrated in (a) of FIG. 3, the discharging table is selected between a time point t5 after the reference time B2 and a time point t6 of an unstable voltage. Meanwhile, in the state illustrated in (b) of FIG. 3, the discharging table is selected between a time point t15 of stable voltage and a time point t16 of an unstable voltage. At the time points t6 and t16 of the unstable voltage, the charging or discharging current exceeds a predetermined value with which the open voltage is determined to be unstable.

On the other hand, if the operation unit 24 determines that the discharged capacity is smaller than the reference capacity A1 in step S35 and the operation unit 24 determines that the elapsed time is shorter than the reference time B2 in step S37, the operation unit 24 determines whether the discharged capacity from the time point of ending discharging is shorter than a predetermined second reference time A2 in step S39. The reference time A2 is shorter than the reference time B2. In a case where the operation part 24 determines that the elapsed time is not shorter than the reference time A2, the elapsed time from the time point t2 of ending charging is long and it is difficult to determine whether the open voltage detected by the voltage detector 21 is the open voltage after charging or the open voltage after discharging. Therefore, the register value of the charging rate is not updated.

The operation part 24 determines that the open voltage detected by the voltage detector 21 is the “open voltage after discharging” in the case where the elapsed time from the time point of ending charging is shorter than the reference time A2, and selects the charging table as a table for calculating the charging rate in step S41. For example, in the state illustrated in (a) of FIG. 3, the charging table is selected between the time point t3 of the stable voltage and the time point t4 after the reference time A2.

The operation part 24 calculates the charging rate corresponding to the open voltage which is corrected in conformity with the condition of 25° C. in step S29 as the residual quantity state of the secondary battery 10 based on the property data indicative of the “charging table” stored in the memory 23 and updates by changing the register value of the charging rate to the calculation value in step S43.

Therefore, within the above embodiment, the open voltage after charging and the open voltage after discharging can be distinguishably measured, and the charging table or the discharging table is selectively applied to a table for calculating the charging rate. Therefore, an accurate charging rate can be constantly calculated irrespective of charging and discharging.

Although the invention has been described with respect to specific embodiments for a complete and clear disclosure, the appended claims are not to be thus limited but are to be construed as embodying all modifications and alternative constructions that may occur to one skilled in the art that fairly fall within the basic teachings herein set forth.

For example, referring to FIG. 2, the property graph c in the no load state after charging and/or the property graph d in the no load state after discharging may be expressed by an approximate polynomial model function by curve fitting, and coefficients of terms may be previously stored in the memory 23. With this, the capacity of the memory 23 can be reduced in comparison with a case where the open voltage data for each charging rate are directly stored.

The international application is based on Japanese Priority Patent Application No. 2010-035128 filed on Feb. 19, 2010, the entire contents of Japanese Priority Patent Application No. 2010-035128 are hereby incorporated herein by reference.

### EXPLANATION OF REFERENCE SIGNS

1: battery monitoring system
10: secondary battery
20: battery condition detecting apparatus
21: voltage detector
22: temperature detector
23: memory
24: operation part
26: calculation part for stabilization waiting time
27: current detector

1. A battery condition detecting apparatus comprising:
a voltage detecting unit configured to detect an open voltage of a secondary battery; and
a charging rate calculating unit configured to
calculate a charging rate by applying a charged open voltage obtained by charging the secondary battery and detected by the voltage detecting unit to first battery property indicative of a relationship between the charged open voltage and the first battery property, and
calculate the charging rate by applying a discharged open voltage obtained by discharging the secondary battery and detected by the voltage detecting unit to second battery property indicative of a relationship between the discharged open voltage and the second battery property.

2. The battery condition detecting apparatus according to claim 1,
wherein the charging rate calculating unit calculates the charging rate by selecting application of the second battery property when a discharged capacity obtained after discharging the secondary battery is a first reference capacity or greater.

3. The battery condition detecting apparatus according to claim 2,
wherein the charging rate calculating unit calculates the charging rate by selecting application of the second battery property in a case where the discharged capacity of the secondary battery is smaller than the first reference capacity and where an elapsed time after ending charging the secondary battery is a first reference time or longer.

4. The battery condition detecting apparatus according to claim 3,
wherein the charging rate calculating unit calculates the charging rate by selecting application of the first battery property in a case where the discharged capacity of the secondary battery is smaller than the first reference capacity and where the elapsed time after ending charging the secondary battery is shorter than the first reference time.

5. The battery condition detecting apparatus according to claim 1, further comprising:
a storage unit configured to store first property data for specifying the first battery property and second property data for specifying second battery property,
wherein any one of open voltage data forming the first property data and other open voltage data forming the second property data is expressed by difference voltage data indicative of a difference between the open voltage data and the other open voltage data.

6. A battery condition detecting method comprising:
detecting an open voltage of a secondary battery;
calculating a charging rate by applying a charged open voltage obtained by charging the secondary battery and detected by the detecting to a first battery property indicative of a relationship between the charged open voltage and the charging rate of the secondary battery; and
further calculating the charging rate by applying a discharged open voltage obtained by discharging the secondary battery and detected by the detecting to a second battery property indicative of a relationship between the discharged open voltage and the charging rate of the secondary battery.

7. The battery condition detecting method according to claim 6,
wherein the charging rate is calculated by selecting application of the charging using the second battery property when a discharged capacity obtained after discharging the secondary battery is a first reference capacity or greater.

8. The battery condition detecting method according to claim 7,
wherein the calculating the charging rate calculates the charging rate by selecting application of the second battery property in a case where the discharged capacity of the secondary battery is smaller than the first reference capacity and where an elapsed time after ending charging the secondary battery is a first reference time or longer.

9. The battery condition detecting method according to claim 8,
wherein the calculating the charging rate calculates the charging rate by selecting application of the first battery property in a case where the discharged capacity of the secondary battery is smaller than the first reference capacity and where the elapsed time after ending charging the secondary battery is shorter than the first reference time.

10. The battery condition detecting method according to claim 6, further comprising:
storing first property data for specifying the first battery property and second property data for specifying second battery property,
wherein any one of open voltage data forming the first property data and other open voltage data forming the second property data is expressed by difference voltage data indicative of a difference between the open voltage data and the other open voltage data.
